(19) United States
(12) Patent Application Publication
(10) Pub. No.: US 2024/0421006 A1
(43) Pub. Date: Dec. 19, 2024

(54) MEASUREMENT METHOD, PEELING METHOD, AND PEELING STRENGTH MEASURING APPARATUS

(71) Applicant: Yamaha Robotics Holdings Co., Ltd., Tokyo (JP)

(72) Inventors: HIROSHI KIKUCHI, Tokyo (JP); Yuta Tobari, Tokyo (JP); Hayato Hishinuma, Tokyo (JP)

(73) Assignee: Yamaha Robotics Holdings Co., Ltd., Tokyo (JP)

(21) Appl. No.: 18/731,375

(22) Filed: Jun. 3, 2024

(30) Foreign Application Priority Data
Jun. 13, 2023 (JP) 2023-096915

(51) Int. Cl. H01L 21/66; B32B 43/00; H01L 21/683

(52) U.S. Cl. CPC H01L 22/12; B32B 43/006; H01L 21/6835; B32B 2457/14; H01L 2221/6839

(57) ABSTRACT

A measurement method measures bonding strength by peeling off a semiconductor chip bonded to a main surface of a substrate by using a blade having a first tool part, which has a blade angle as a first acute angle, and a second tool part provided on first tool part. The method includes: inserting first tool part along main surface toward a chamfered outer peripheral edge part of chip; while first tool part is inserted into the edge part, peeling off chip from substrate by bringing second tool part provided on first tool part into contact with the edge part of chip and applying a force to chip away from substrate; and measuring bonding strength between substrate and chip based on a length from a contact point where first tool part or second tool part comes into contact with chip to a point where chip and substrate are peeled apart.

### CROSS-REFERENCE TO RELATED APPLICATIONS

This application claims the priority benefits of Japanese application no. 2023-096915, filed on Jun. 13, 2023. The entity of the above-mentioned patent application is hereby incorporated by reference herein and made a part of this specification.

### BACKGROUND

### Technical Field

The present invention relates to a measurement method, a peeling method, and a peeling strength measuring apparatus.

### Related Art

A method is known in which a blade is inserted into the bonding surfaces of two bonded substrates to peel the substrates apart, and the bonding strength is measured based on the peeling length. For example, Patent Document 1 discloses evaluating the bonding strength of substrates using such a blade insertion method. Specifically, the bonding strength of the substrates may be evaluated from values such as the length of the crack between the substrates caused by peeling off the substrates, the thickness of the blade, and the respective thicknesses of the two substrates.

### CITATION LIST

### Patent Literature

[Patent Literature 1] Patent No. JP 4348454

However, when performing the blade insertion method using a single blade on the bonding surfaces of two such substrates, there are cases where the substrates are not easily peeled apart from each other, such as when the substrates are firmly bonded to each other, or when the substrates are bonded to each other again even after being peeled apart.

The present invention has been made in consideration of the above circumstances, and an object of the present invention is to provide a measurement method, a peeling method, and a peeling strength measuring apparatus that make it possible to easily peel a semiconductor chip from a substrate.

### SUMMARY

A measurement method according to one aspect of the present invention is one for measuring bonding strength by peeling off a semiconductor chip bonded to a main surface of a substrate by using a blade having a first tool part, which has a blade angle as a first acute angle, and a second tool part provided on the first tool part. The method includes: the first tool part is inserted along the main surface toward a chamfered outer peripheral edge part of the semiconductor chip; while the first tool part is inserted into the outer peripheral edge part, the semiconductor chip is peeled off from the substrate by bringing the second tool part provided on the first tool part into contact with the outer peripheral edge part of the semiconductor chip and applying a force to the semiconductor chip in a direction away from the substrate; and the bonding strength between the substrate and the semiconductor chip is measured based on a length from a contact point where the first tool part or the second tool part comes into contact with the semiconductor chip to a point where the semiconductor chip and the substrate are peeled apart.

A peeling method according to one aspect of the present invention is one for peeling off a semiconductor chip bonded to a main surface of a substrate by using a blade having a first tool part, which has a blade angle as a first acute angle, and a second tool part provided on the first tool part. The method includes: the first tool part is inserted along the main surface toward a chamfered outer peripheral edge part of the semiconductor chip; and while the first tool part is inserted into the outer peripheral edge part, the semiconductor chip is peels off from the substrate by bringing the second tool part provided on the first tool part into contact with the outer peripheral edge part of the semiconductor chip and applying a force to the semiconductor chip in a direction away from the substrate.

A peeling strength measuring apparatus according to one aspect of the present invention is a peeling apparatus for peeling off a semiconductor chip bonded to a main surface of a substrate. The apparatus includes: a blade having a first tool part, which has a blade angle as a first acute angle, and a second tool part provided on the first tool part; and a measuring part. While the first tool part is inserted along the main surface toward the chamfered outer peripheral edge part of the semiconductor chip, the second tool part comes into contact with the outer peripheral edge part of the semiconductor chip and applies a force to the semiconductor chip in a direction away from the substrate. The measuring part measures the bonding strength between the substrate and the semiconductor chip based on a length from a contact point where the first tool part or the second tool part comes into contact with the semiconductor chip to a point where the semiconductor chip and the substrate are peeled apart.

### BRIEF DESCRIPTION OF THE DRAWINGS

FIG. 1 is a cross-sectional diagram showing an example of a semiconductor module to which a measurement method according to a first embodiment may be applied.

FIG. 2 is a block diagram showing an example of a peeling strength measuring apparatus configured in the measurement method according to the first embodiment.

FIG. 3 is a perspective diagram showing an example of a blade configured in the measurement method according to the first embodiment.

FIG. 4 is a flowchart showing a measurement method according to the first embodiment.

FIG. 5 is a diagram showing an example when the measurement method according to the first embodiment is performed.

FIG. 6A is a cross-sectional diagram showing an example of a measurement method according to the first embodiment during execution.

FIG. 6B is a cross-sectional diagram showing an example of the measurement method according to the first embodiment during execution.

FIG. 6C is a cross-sectional diagram showing an example of the measurement method according to the first embodiment during execution.

FIG. 7 is a cross-sectional diagram showing another example of the measurement method according to the first embodiment during execution.

FIG. 8A is a cross-sectional diagram showing an example of a measurement method according to a second embodiment during execution.

FIG. 8B is a cross-sectional diagram showing an example of the measurement method according to the second embodiment during execution.

FIG. 8C is a cross-sectional diagram showing an example of a measurement method according to the second embodiment during execution.

### DESCRIPTION OF THE EMBODIMENTS

A measurement method according to one aspect of the present invention is one for measuring bonding strength by peeling off a semiconductor chip bonded to a main surface of a substrate by using a blade having a first tool part, which has a blade angle as a first acute angle, and a second tool part provided on the first tool part. The method includes: the first tool part is inserted along the main surface toward a chamfered outer peripheral edge part of the semiconductor chip; while the first tool part is inserted into the outer peripheral edge part, the semiconductor chip is peeled off from the substrate by bringing the second tool part provided on the first tool part into contact with the outer peripheral edge part of the semiconductor chip and applying a force to the semiconductor chip in a direction away from the substrate; and the bonding strength between the substrate and the semiconductor chip is measured based on a length from a contact point where the first tool part or the second tool part comes into contact with the semiconductor chip to a point where the semiconductor chip and the substrate are peeled apart.

According to this aspect, with respect to a semiconductor chip bonded to a main surface of a substrate, a first tool part is inserted along the main surface toward the chamfered outer peripheral edge part of the semiconductor chip, a second tool part provided on the first tool part is brought into contact with the outer peripheral edge part of the semiconductor chip, and a force is applied to the semiconductor chip in a direction away from the substrate. That is, a semiconductor chip having a chamfered outer peripheral edge part and bonded to a substrate is peeled off using a first tool part having a blade angle that facilitates entry into the bonding surface, and a second tool part that applies a force in a direction away from the substrate to the semiconductor chip. As a result, the semiconductor chip can be easily peeled off from the substrate. Thus, the bonding strength between the semiconductor chip and the substrate can be easily measured.

A peeling method according to one aspect of the present invention is one for peeling off a semiconductor chip bonded to a main surface of a substrate by using a blade having a first tool part, which has a blade angle as a first acute angle, and a second tool part provided on the first tool part. The method includes: the first tool part is inserted along the main surface toward a chamfered outer peripheral edge part of the semiconductor chip; and while the first tool part is inserted into the outer peripheral edge part, the semiconductor chip is peels off from the substrate by bringing the second tool part provided on the first tool part into contact with the outer peripheral edge part of the semiconductor chip and applying a force to the semiconductor chip in a direction away from the substrate.

According to this aspect, with respect to a semiconductor chip bonded to a main surface of a substrate, a first tool part is inserted along the main surface toward the chamfered outer peripheral edge part of the semiconductor chip, a second tool part provided on the first tool part is brought into contact with the outer peripheral edge part of the semiconductor chip, and a force is applied to the semiconductor chip in a direction away from the substrate. That is, a semiconductor chip having a chamfered outer peripheral edge part and bonded to a substrate is peeled off using a first tool part having a blade angle that facilitates entry into the bonding surface, and a second tool part that applies a force in a direction away from the substrate to the semiconductor chip. As a result, the semiconductor chip can be easily peeled off from the substrate.

A peeling strength measuring apparatus according to one aspect of the present invention is a peeling apparatus for peeling off a semiconductor chip bonded to a main surface of a substrate. The apparatus includes: a blade having a first tool part, which has a blade angle as a first acute angle, and a second tool part provided on the first tool part; and a measuring part. While the first tool part is inserted along the main surface toward the chamfered outer peripheral edge part of the semiconductor chip, the second tool part comes into contact with the outer peripheral edge part of the semiconductor chip and applies a force to the semiconductor chip in a direction away from the substrate. The measuring part measures the bonding strength between the substrate and the semiconductor chip based on a length from a contact point where the first tool part or the second tool part comes into contact with the semiconductor chip to a point where the semiconductor chip and the substrate are peeled apart.

According to this aspect, a semiconductor chip having a chamfered outer peripheral edge part and bonded to a substrate is peeled off using a first tool part having a blade angle that facilitates entry into the bonding surface, and a second tool part that applies a force in a direction away from the substrate to the semiconductor chip. By using a peeling apparatus equipped with such a blade, it becomes possible to easily peel the semiconductor chip from the substrate. Thus, the bonding strength between the two may be easily measured.

According to the present invention, it is possible to provide a measurement method, a peeling method, and a peeling strength measuring apparatus that enable a semiconductor chip to be easily peeled off from a substrate.

Hereinafter, embodiments of the present invention will be described with reference to the drawings. The drawings of each embodiment are merely examples, and the dimensions and shapes of each part are schematic, and the technical scope of the present invention should not be interpreted as being limited to each embodiment.

### First Embodiment

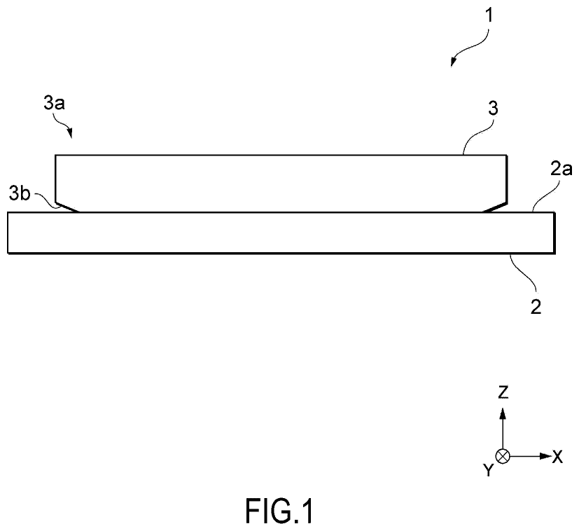

In FIG. 1, for the purpose of describing relative directional relationships, the rightward direction on the paper surface is called the X-axis positive direction, the rearward direction on the paper surface is called the Y-axis positive direction, and the upward direction on the paper surface is called the Z-axis positive direction. The leftward direction on the paper surface is called the X-axis negative direction, the frontward direction on the paper surface is called the Y-axis negative direction, and the downward direction on the paper surface is called the Z-axis negative direction.

FIG. 1 is a cross-sectional diagram showing an example of a semiconductor module to which a measurement method according to a first embodiment may be applied. A semiconductor module 1 includes a semiconductor wafer 2 and a semiconductor chip 3. An outer peripheral edge part 3a of the semiconductor chip 3 is chamfered. The outer peripheral edge part 3a may be chamfered, for example, so as to have an inclined surface 3b with respect to a main surface 2a of the semiconductor wafer 2. One surface of the semiconductor chip 3 may be bonded to the main surface 2a of the semiconductor wafer 2 by electrostatic force. In the following description, the semiconductor wafer 2 will be described as an example of a substrate applicable to the measurement method according to the first embodiment, but the substrate may be made of various glass, ceramics, resin, or the like in addition to various metals and alloys.

### [Peeling Strength Measuring Apparatus Configured in the Measurement Method According to the First Embodiment]

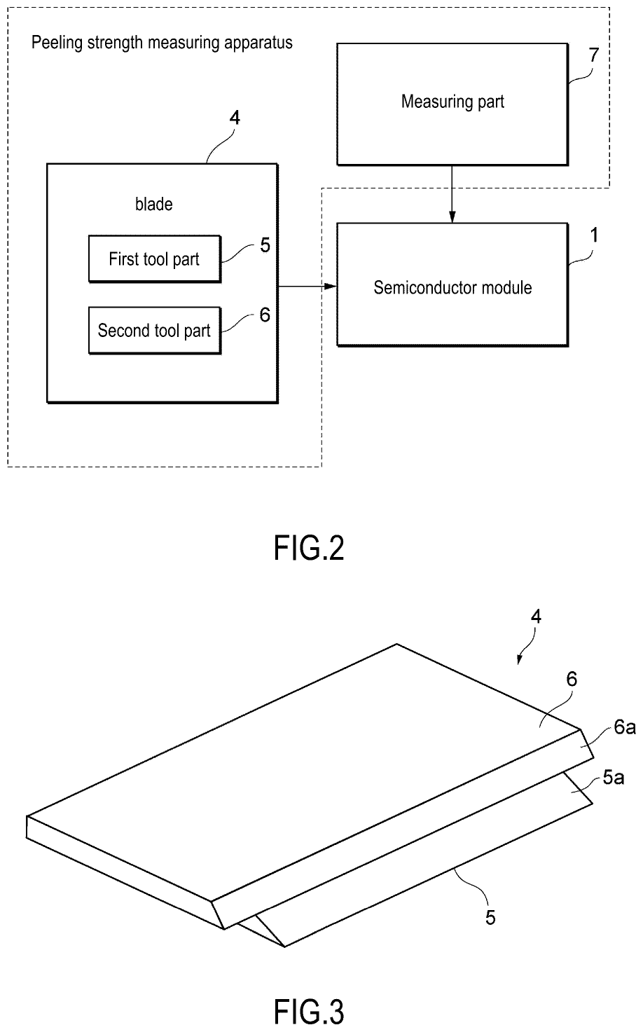

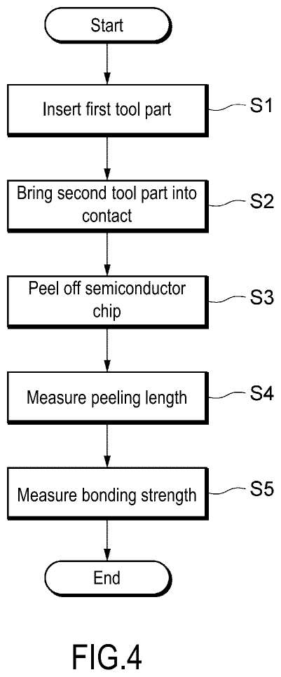

FIG. 2 is a diagram showing an example of a peeling strength measuring apparatus configured in the measurement method according to the first embodiment. The peeling strength measuring apparatus according to the first embodiment includes a blade 4 that peels the semiconductor chip 3 from the semiconductor wafer 2, and a measuring part 7 that measures the bonding strength between the semiconductor wafer 2 and the semiconductor chip 3. Steps S1 to S5 shown in FIG. 4, which will be described later, describe an example performed using the peeling strength measuring apparatus according to the first embodiment. The measuring part 7 may be a measuring apparatus including, for example, an edge sensor, a surface potential measuring sensor, and the like.

FIG. 3 is a perspective diagram showing an example of a blade configured in the measurement method according to the first embodiment. The blade 4 includes a first tool part 5 and a second tool part 6. The blade 4 has, for example, the first tool part 5 having a first blade surface 5a and the second tool part 6 having a second blade surface 6a provided thereon. Moreover, the widthwise length of the second tool part 6 may be larger than the widthwise length of the first tool part 5, and the first and second tool parts 5, 6 may be provided in fixed relative positions to each other. With such a configuration, it is possible to enhance the effect of preventing the first and second tool parts 5, 6 from buckling against each other. As will be described later, the first and second tool parts 5, 6 may be configured to be movable relative to each other.

FIG. 4 is a flowchart showing a measurement method according to the first embodiment. The measurement method according to the first embodiment proceeds according to steps S1 to S5. The flowchart will be described below with reference to FIGS. 4, 5, and 6A to 6C as appropriate.

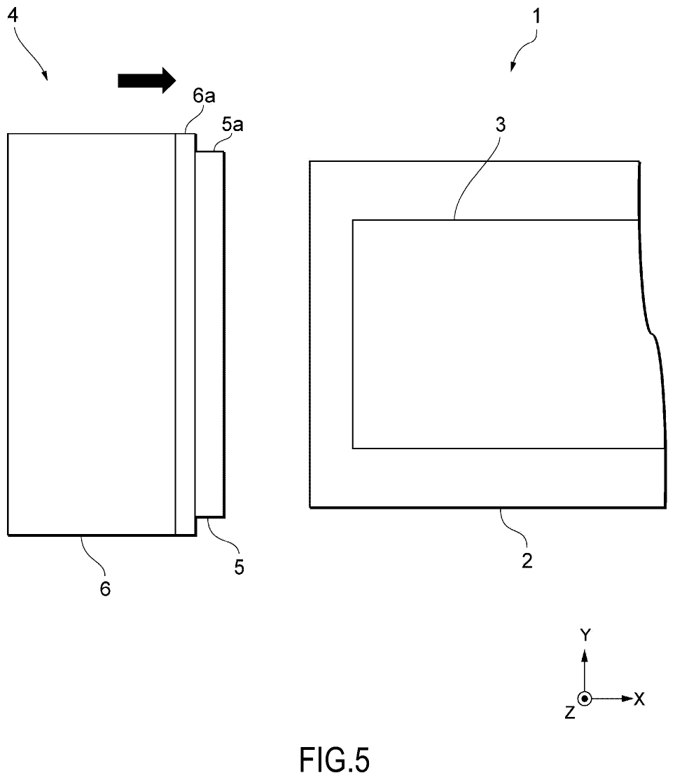

FIG. 5 is a diagram showing an example when the measurement method according to the first embodiment is performed. The blade 4 is inserted into the semiconductor module 1 in an insertion direction (the X-axis positive direction). The widthwise (the Y-axis positive direction) length of each of the first tool part 5 and the second tool part 6 may be larger than the widthwise (the Y-axis positive direction) length of the chamfered outer peripheral edge part 3a of the semiconductor chip 3, i.e., the widthwise length of the inclined surface 3b. With such a configuration, peeling is performed by making line contact with the entire inclined surface 3b surface of the semiconductor chip 3 in the width direction (the Y-axis positive direction) with a smaller contact area, thus peeling can be performed with less friction.

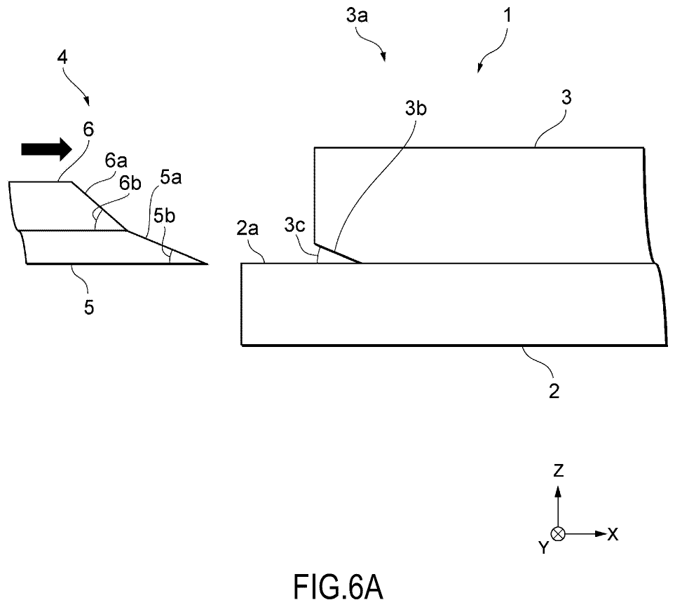

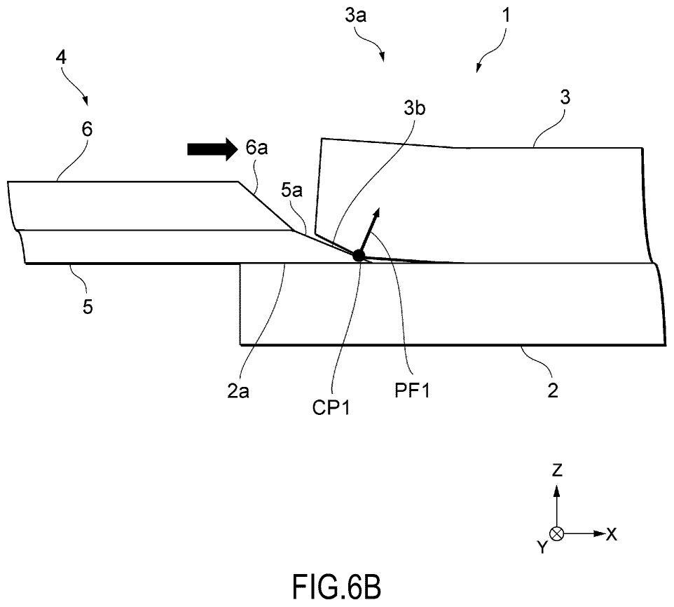

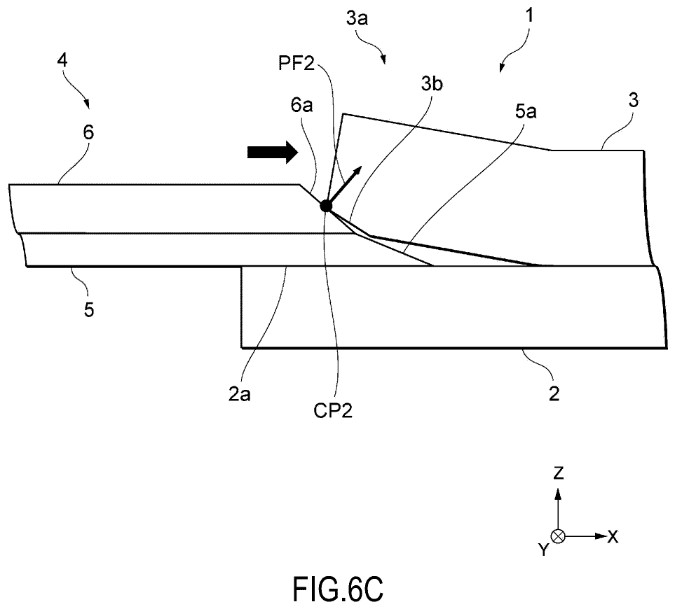

FIG. 6A is a cross-sectional diagram showing an example of a measurement method according to the first embodiment during execution. The blade 4 is inserted toward the chamfered outer peripheral edge part 3a of the semiconductor chip 3. That is, the first tool part 5 having a blade angle as a first acute angle 5b is inserted in the X-axis positive direction along the main surface 2a toward the inclined surface 3b.

The blade angle as the first acute angle 5b of the first tool part 5 is set to be smaller than a formed angle 3c formed by the inclined surface 3b of the semiconductor chip 3 and the main surface 2a. The blade angle as a second acute angle 6b of the second tool part 6 is set to be larger than the blade angle as the first acute angle 5b. By adopting such an angle relationship, the first tool part 5 may more easily insert between the semiconductor chip 3 and the semiconductor wafer 2, and force may be more easily applied to the semiconductor chip 3 by the second tool part 6 in a direction away from the semiconductor wafer 2. Moreover, the combination of the first acute angle 5b, the second acute angle 6b, and the formed angle 3c shown in FIG. 6A is merely an example, and other combinations of relative sizes of these angles may be adopted.

In step S1, the first tool part 5 is inserted. As shown in FIG. 6B, the first tool part 5 is inserted into the outer peripheral edge part 3a of the semiconductor chip 3. At this time, the first blade surface 5a of the first tool part 5 may come into contact with the inclined surface 3b of the semiconductor chip 3.

FIG. 6B is a cross-sectional diagram showing an example of the measurement method according to the first embodiment during execution. While the first tool part 5 is inserted into the outer peripheral edge part 3a, the first blade surface 5a of the first tool part 5 comes into contact with the inclined surface 3b of the semiconductor chip 3 at a contact point CP1, making line contact along the Y-axis positive direction. At this time, a peeling force PF1 acts in a direction perpendicular to the first blade surface 5a of the first tool part 5 (a direction between the X-axis positive direction and the Z-axis positive direction), peeling off the semiconductor chip 3 from the main surface 2a of the semiconductor wafer 2. Moreover, the state in which the first tool part 5 is inserted into the outer peripheral edge part 3a refers to a state in which the first blade surface 5a and the outer peripheral edge part 3a overlap in a planar view (not shown), including a state in which the first tool part 5 is in contact with the semiconductor chip 3.

In step S2, the second tool part 6 is brought into contact. As shown in FIG. 6C, the second tool part 6 is brought into contact with the inclined surface 3b of the semiconductor chip 3.

FIG. 6C is a cross-sectional diagram showing an example of the measurement method according to the first embodiment during execution. While the first tool part 5 is inserted into the outer peripheral edge part 3a, the second blade surface 6a of the second tool part 6 comes into contact with the inclined surface 3b of the semiconductor chip 3 at a contact point CP2, making line contact along the Y-axis positive direction. At this time, a peeling force PF2 acts in a direction perpendicular to the second blade surface 6a of the second tool part 6 (a direction between the X-axis positive direction and the Z-axis positive direction), peeling off the semiconductor chip 3 from the main surface 2a of the semiconductor wafer 2. Thereafter, the blade 4 is advanced in the X-axis positive direction, whereby the semiconductor chip 3 is gradually peeled off from the main surface 2a of the semiconductor wafer 2. Moreover, the state in which the first tool part 5 is inserted into the outer peripheral edge part 3a refers to a state in which the first blade surface 5a and the outer peripheral edge part 3a overlap in a planar view (not shown), including a state in which the first tool part 5 is not in contact with the semiconductor chip 3.

In step S3, the semiconductor chip 3 is peeled off. In FIG. 6C, the blade 4 is advanced in the X-axis positive direction, whereby the semiconductor chip 3 is gradually peeled off from the main surface 2a of the semiconductor wafer 2. For example, the blade 4 is brought into contact with the semiconductor chip 3 and advanced a predetermined distance in the X-axis positive direction, thereby peeling off the semiconductor chip 3 off from the main surface 2a of the semiconductor wafer 2.

In step S4, the peeling length is measured. For example, the blade 4 is brought into contact with the semiconductor chip 3 and advanced a predetermined distance in the X-axis positive direction, and the length from the contact point between the blade 4 and the semiconductor chip 3 to the point where the semiconductor chip 3 and the semiconductor wafer 2 are peeled apart is measured.

In step S5, the bonding strength is measured. The bonding strength is measured by using, for example, a value calculated as the bonding strength as a measured value by using previously obtained thickness of the blade 4, thickness of the semiconductor wafer 2, thickness of the semiconductor chip 3, and the peeling length measured in step S4. Moreover, the bonding strength may be measured using the measuring part 7.

The bonding strength between the semiconductor chip 3 and the semiconductor wafer 2 may be evaluated using a bond energy of the bonding surface. The bond energy may be calculated by the following equation:

$$\\ \begin{matrix}γ = \frac{3 {E}^{{}_{} *} {u}^{{}_{} 2} {w}^{{}_{} 3}}{32 {l}^{{}_{} 4}} & [ Equation 1 ]\end{matrix}$$

A bond energy γ is obtained from u=overall blade thickness, l=peeling length, w=thickness of the semiconductor chip, and Young's modulus E*.

According to the above aspect, by setting the blade angle as the first acute angle 5b of the first tool part 5 to be smaller than the formed angle formed by the inclined surface 3b of the semiconductor chip 3 and the main surface 2a, the contact area between the first tool part 5 and the semiconductor chip 3 is reduced and the frictional force is reduced, and entry is facilitated. Further, by setting the blade angle as the second acute angle 6b of the second tool part 6 to be larger than the blade angle as the first acute angle 5b, the semiconductor chip 3 is acted in a direction away from the semiconductor wafer 2. By using the blade 4 having such a first tool part 5 and second tool part 6, the chamfered semiconductor chip 3 may be easily peeled off from the semiconductor wafer 2.

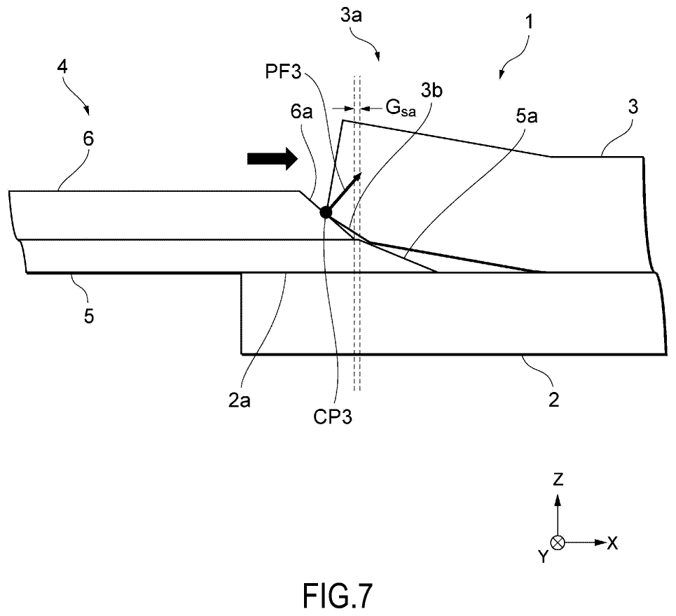

FIG. 7 is a cross-sectional diagram showing another example of the measurement method according to the first embodiment during execution. The first tool part 5 may be configured to be movable relative to the second tool part 6. The example shown in FIG. 7 shows a stage in which the first tool part 5 is moving relatively to the second tool part 6, in other words, it is relatively displaced from the initial position via a gap Gsa. With such a configuration, by inserting the first tool part 5 with the height from the main surface 2a of the semiconductor wafer 2 to a contact point CP3 maintained constant, the semiconductor chip 3 can be peeled off while suppressing warping thereof.

### Second Embodiment

The measurement method according to the second embodiment differs from the measurement method according to the first embodiment in that the chamfering depth of an outer peripheral edge part 30a of a semiconductor chip 30 is longer in the X-axis positive direction. In other words, an aspect is shown in which, unlike the first embodiment, the second tool part 6 comes into contact with the outer peripheral edge part 3a of the semiconductor chip 3 before the first tool part 5 comes into contact with the outer peripheral edge part 3a of the semiconductor chip 3. In the following description of the measurement method according to the second embodiment, the same contents as those of the measurement method according to the first embodiment will be omitted.

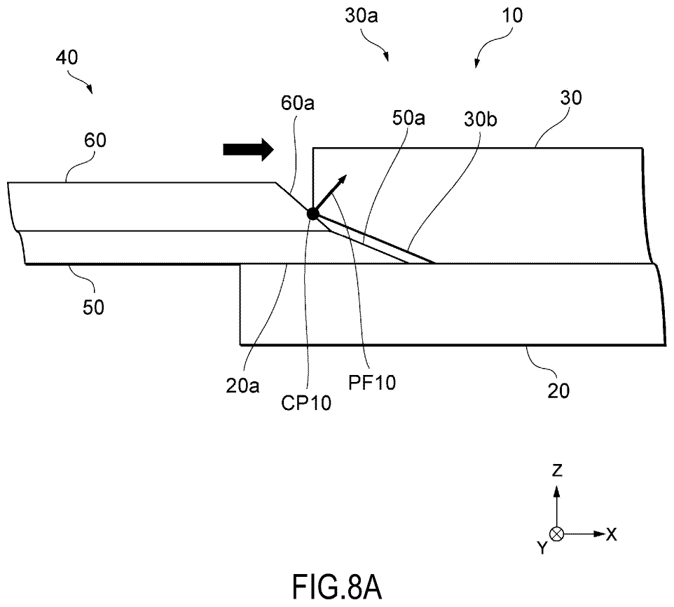

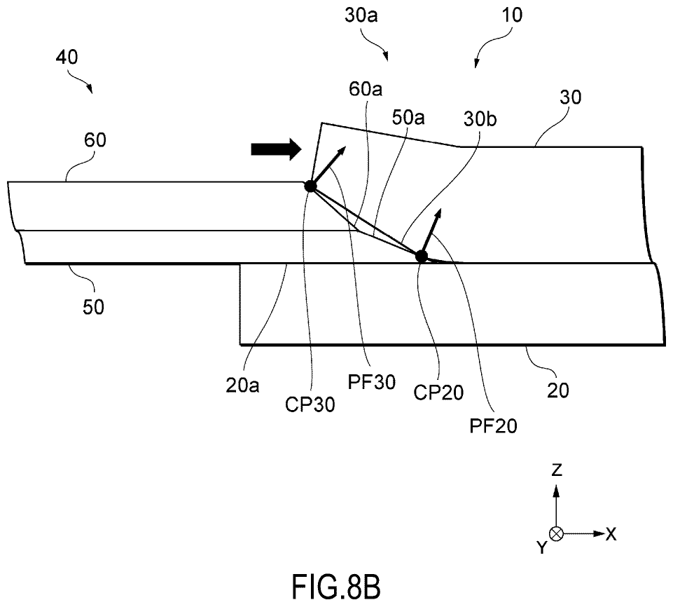

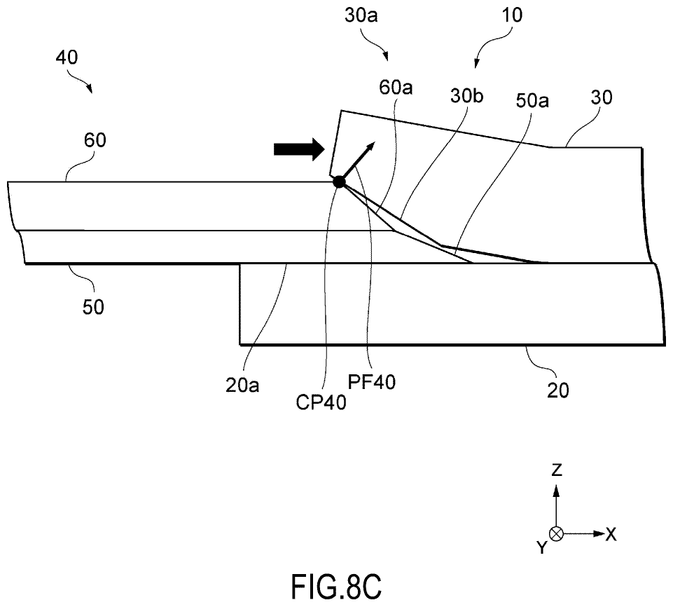

FIG. 8A is a cross-sectional diagram showing an example of a measurement method according to the second embodiment during execution. While a first tool part 50 is inserted into the outer peripheral edge part 30a, a second blade surface 60a of a second tool part 60 comes into contact with an inclined surface 30b of the semiconductor chip 30 at a contact point CP10, making line contact along the Y-axis positive direction. In the measurement method according to the second embodiment, the blade 40 is advanced in the X-axis positive direction along a main surface 20a, so that the second tool part 60 comes into contact with the inclined surface 30b first.

FIG. 8B is a cross-sectional diagram showing an example of the measurement method according to the second embodiment during execution. In FIG. 8B, the force of the blade 40 for peeling is not sufficient, and the semiconductor chip 30 remains bonded to the main surface 20a of a semiconductor wafer 20. At this time, while the first tool part 50 is inserted into the outer peripheral edge part 30a, a first blade surface 50a of the first tool part 50 comes into contact with the inclined surface 30b of the semiconductor chip 30 at a contact point CP20, making line contact along the Y-axis positive direction. Further, the second blade surface 60a of the second tool part 60 comes into contact with the inclined surface 30b of the semiconductor chip 30 at a contact point CP30, making line contact along the Y-axis positive direction. With such a configuration, at the contact point CP20 and the contact point CP30, the first tool part 50 and the second tool part 60 can peel the semiconductor chip 30 from the main surface 20a of the semiconductor wafer 20 by applying peeling forces PF20 and PF30 to the semiconductor chip 30, respectively.

FIG. 8C is a cross-sectional diagram showing an example of the measurement method according to the second embodiment during execution. While the first tool part 50 is inserted into the outer peripheral edge part 30a, the second blade surface 60a of the second tool part 60 comes into contact with the inclined surface 30b of the semiconductor chip 30 at a contact point CP40, making line contact along the Y-axis positive direction, and a peeling force PF40 acts in a direction perpendicular to the second blade surface 60a (a direction between the X-axis positive direction and the Z-axis positive direction), peeling off the semiconductor chip 30 from the main surface 20a of the semiconductor wafer 20. Thereafter, the blade 40 is advanced in the X-axis positive direction, whereby the semiconductor chip 30 is gradually peeled off from the main surface 20a of the semiconductor wafer 20.

According to the above embodiment, even if the chamfering depth is long in the X-axis positive direction and the force of the blade 40 for peeling is insufficient, the semiconductor chip 30 is acted in a direction away from the semiconductor wafer 20 using the second tool part 60 having a blade angle as a second acute angle 60b set to be larger than the blade angle as a first acute angle 50b. Further, by using the first tool part 50 having a blade angle as the first acute angle 50b set to be smaller than the formed angle formed by the inclined surface 30b of the semiconductor chip 30 and the main surface 20a to reduce the contact area between the first tool part 50 and the semiconductor chip and reduce friction force for entry, the semiconductor chip 30 can be easily peeled off from the semiconductor wafer 20.

The measurement methods according to the first and second embodiments have been described above. A peeling method according to the embodiments of the present invention will be described with reference to FIGS. 1 to 6C which are related to the measurement method according to the first embodiment.

### [An Example of a Peeling Method According to the Embodiments of the Present Invention]

As an example of the peeling method according to the embodiments of the present invention, the method may be performed using the semiconductor module 1 and the blade 4 shown in FIGS. 1 and 3. In an example of the peeling method according to the embodiment of the present invention, steps S1 to S3 shown in FIG. 4 are performed in the order as in the measurement method according to the first embodiment. S1 to S2 are the same as in the measurement method according to the first embodiment, and thus will be omitted. In an example of the peeling method according to the embodiment of the present invention, the semiconductor chip 3 may be completely peeled off from the main surface 2a of the semiconductor wafer 2 by advancing the blade 4 in the X-axis positive direction as shown in FIG. 6C.

The above-described embodiment is intended to facilitate understanding of the present invention, and is not intended to limit the present invention. The present invention may be modified or improved without departing from the spirit thereof, and the present invention also includes equivalents thereof. In other words, even if a person skilled in the art makes appropriate design modifications to each embodiment, they are included within the scope of the present invention as long as they have the features of the present invention. For example, the elements of each embodiment and their arrangement, materials, conditions, shapes, sizes, etc. are not limited to those exemplified, and may be changed as appropriate. Further, the elements of each embodiment may be combined to the extent technically possible, and such combinations are also included within the scope of the present invention as long as they include the features of the present invention.

### (Supplementary Note 1)

A measurement method according to the embodiment is one for measuring bonding strength by peeling off a semiconductor chip bonded to a main surface of a substrate by using a blade having a first tool part, which has a blade angle as a first acute angle, and a second tool part provided on the first tool part, the method including: inserting the first tool part along the main surface toward a chamfered outer peripheral edge part of the semiconductor chip; while the first tool part is inserted into the outer peripheral edge part, peeling off the semiconductor chip from the substrate by bringing the second tool part provided on the first tool part into contact with the outer peripheral edge part of the semiconductor chip and applying a force to the semiconductor chip in a direction away from the substrate; and measuring the bonding strength between the substrate and the semiconductor chip based on a length from a contact point where the first tool part or the second tool part comes into contact with the semiconductor chip to a point where the semiconductor chip and the substrate are peeled apart.

### (Supplementary Note 2)

In the measurement method according to Supplementary Note 1, the outer peripheral edge part is chamfered into an inclined surface.

### (Supplementary Note 3)

The measurement method of any one of Supplementary Notes 1 to 2, wherein the second tool part has a blade angle as a second acute angle.

### (Supplementary Note 4)

In the measurement method according to any one of Supplementary Note 1 to Supplementary Note 3, an angle of the first acute angle of the first tool part is smaller than an angle of the second acute angle of the second tool part.

(Supplementary Note 5) In the measurement method according to any one of Supplementary Note 1 to Supplementary Note 4, an angle of first acute angle of the first tool part is smaller than a formed angle formed by the inclined surface and the main surface.

### (Supplementary Note 6)

In the measurement method according to any one of Supplementary Notes 1 to 5, inserting the first tool part along the main surface includes bringing the first tool part into contact with the outer peripheral edge part before the second tool part.

### (Supplementary Note 7)

In the measurement method according to any one of Supplementary Notes 1 to 6, inserting the first tool part along the main surface includes bringing the second tool part into contact with the outer circumferential end part before the first tool part.

### (Supplementary Note 8)

In the measurement method according to any one of Supplementary Note 1 to Supplementary Note 7, inserting the first tool part along the main surface includes moving the first tool part relative to the second tool part.

### (Supplementary Note 9)

In the measurement method according to any one of Supplementary Notes 1 to 8, inserting the first tool part along the main surface includes moving the first tool part and the second tool part while fixing their relative positions to each other.

### (Supplementary Note 10)

In the measurement method according to any one of Supplementary Notes 1 to 9, a widthwise length of each of the first tool part and the second tool part is larger than a widthwise length of the chamfered outer peripheral edge part of the semiconductor chip.

### (Supplementary Note 11)

In the measurement method according to any one of Supplementary Note 1 to Supplementary Note 10, the substrate is a semiconductor wafer.

### (Supplementary Note 12)

In the measurement method according to any one of Supplementary Note 1 to Supplementary Note 11, the measurement method includes peeling off the semiconductor chip bonded to the main surface of the substrate by electrostatic force.

### (Supplementary Note 13)

A peeling method according to the embodiment is one for peeling off a semiconductor chip bonded to a main surface of a substrate by using a blade having a first tool part, which has a blade angle as a first acute angle, and a second tool part provided on the first tool part, the method including: inserting the first tool part along the main surface toward a chamfered outer peripheral edge part of the semiconductor chip; and while the first tool part is inserted into the outer peripheral edge part, peeling off the semiconductor chip from the substrate by bringing the second tool part provided on the first tool part into contact with the outer peripheral edge part of the semiconductor chip and applying a force to the semiconductor chip in a direction away from the substrate.

### (Supplementary Note 14)

The peeling strength measuring apparatus according to the embodiment is a peeling apparatus for peeling off a semiconductor chip bonded to a main surface of a substrate, the apparatus including: a blade having a first tool part, which has a blade angle as a first acute angle, and a second tool part provided on the first tool part; and a measuring part. While the first tool part is inserted along the main surface toward the chamfered outer peripheral edge part of the semiconductor chip, the second tool part comes into contact with the outer peripheral edge part of the semiconductor chip and applies a force to the semiconductor chip in a direction away from the substrate. The measuring part measures the bonding strength between the substrate and the semiconductor chip based on a length from a contact point where the first tool part or the second tool part comes into contact with the semiconductor chip to a point where the semiconductor chip and the substrate are peeled apart.

What is claimed is:

1. A measurement method for measuring bonding strength by peeling off a semiconductor chip bonded to a main surface of a substrate by using a blade having a first tool part, which has a blade angle as a first acute angle, and a second tool part provided on the first tool part, the method comprising:
inserting the first tool part along the main surface toward a chamfered outer peripheral edge part of the semiconductor chip;
while the first tool part is inserted into the outer circumferential end part, peeling off the semiconductor chip from the substrate by bringing the second tool part provided on the first tool part into contact with the outer peripheral edge part of the semiconductor chip and applying a force to the semiconductor chip in a direction away from the substrate; and
measuring the bonding strength between the substrate and the semiconductor chip based on a length from a contact point where the first tool part or the second tool part comes into contact with the semiconductor chip to a point where the semiconductor chip and the substrate are peeled apart.

2. The measurement method according to claim 1, wherein the outer peripheral edge part is chamfered into an inclined surface.

3. The measurement method according to claim 2, wherein the second tool part has a blade angle as a second acute angle.

4. The measurement method according to claim 3, wherein an angle of the first acute angle of the first tool part is smaller than an angle of the second acute angle of the second tool part.

5. The measurement method according to claim 3, wherein an angle of the first acute angle of the first tool part is smaller than a formed angle formed by the inclined surface and the main surface.

6. The measurement method according to claim 1, wherein inserting the first tool part along the main surface comprises bringing the first tool part into contact with the outer peripheral edge part before the second tool part.

7. The measurement method according to claim 1, wherein inserting the first tool part along the main surface comprises bringing the second tool part into contact with the outer peripheral edge part before the first tool part.

8. The measurement method according to claim 1, wherein inserting the first tool part along the main surface comprises moving the first tool part relative to the second tool part.

9. The measurement method according to claim 1, wherein inserting the first tool part along the main surface comprises moving the first tool part and the second tool part while fixing their relative positions to each other.

10. The measurement method according to claim 1, wherein a widthwise length of each of the first tool part and the second tool part is longer than a widthwise length of the chamfered outer peripheral edge part of the semiconductor chip.

11. The measurement method according to claim 1, wherein the substrate is a semiconductor wafer.

12. The measurement method according to claim 1, further comprising peeling off the semiconductor chip bonded to the main surface of the substrate by electrostatic force.

13. A peeling method for peeling off a semiconductor chip bonded to a main surface of a substrate by using a blade having a first tool part that has a blade angle as a first acute angle, and a second tool part provided on the first tool part, the method comprising:
inserting the first tool part along the main surface toward a chamfered outer peripheral edge part of the semiconductor chip; and
while the first tool part is inserted into the outer peripheral edge part, peeling off the semiconductor chip from the substrate by bringing the second tool part provided on the first tool part into contact with the outer peripheral edge part of the semiconductor chip and applying a force to the semiconductor chip in a direction away from the substrate.

14. A peeling strength measuring apparatus, which is a peeling apparatus for peeling off a semiconductor chip bonded to a main surface of a substrate, the apparatus comprising:
a blade having a first tool part, which has a blade angle as a first acute angle, and a second tool part provided on the first tool part; and
a measuring part measuring bonding strength between the substrate and the semiconductor chip,
wherein while the first tool part is inserted along the main surface toward the outer peripheral edge part of the semiconductor chip, the second tool part comes into contact with the chamfered outer peripheral edge part of the semiconductor chip and applies a force to the semiconductor chip in a direction away from the substrate, and
the measuring part measures the bonding strength between the substrate and the semiconductor chip based on a length from a contact point where the first tool part or second tool part comes into contact with the semiconductor chip to a point where the semiconductor chip and the substrate are peeled apart.
